(19) United States
(12) Patent Application Publication
(10) Pub. No.: US 2002/0180469 A1
(43) Pub. Date: Dec. 5, 2002

(54) Reusable test jig

(76) Inventors: Jichen Wu, Hsinchu (TW); Burton Yang, Hsinchu (TW)

Correspondence Address: Keith Kline,, PRO-TECHTOR INTERNATIONAL SERVICES, 20775 Norada Court, Saratoga, CA, 95070-3018, US

(21) Appl. No.: 10/147,132

(22) Filed: May 15, 2002

(30) Foreign Application Priority Data
May 31, 2001 (TW) 090209139
Aug. 1, 2001 (TW) 90213061

(51) Int. Cl. G01R 31/02

(52) U.S. Cl. 324/754

(57) ABSTRACT

The invention provides a reusable test jig including a pin board unit, a plurality of resilient members, a plurality of electroconductive members, a holding plate unit and a plurality of probes. The pin board unit is formed with predetermined pin holes. The electroconductive resilient members are received with the pin holes of the pin board unit, respectively. The electroconductive members are electrically connected to the corresponding resilient members, respectively. The holding plate unit is formed with predetermined holding holes corresponding to the pin holes. At least one holding hole is properly inclined. The probes are inserted into and held by the holding holes of the holding plate unit and electrically contact the resilient members, respectively. Thus, the at least one probe may be properly inclined and contact the to-be-tested device. Accordingly, the signals can be directly transferred from the probes to the electroconductive members via the resilient members, respectively.

### BACKGROUND OF THE INVENTION

1. Field of the Invention

The invention relates to a reusable test jig, and more specifically to a test jig capable of greatly lowering the testing cost and increasing the testing density.

2. Description of the Related Art

In general, after traces are formed in printed circuit boards, the circuit boards have to be tested to make sure that each trace is normally conductive. After the test, the printed circuit boards having perfect electric traces are picked out for electrical elements to be mounted on.

Referring to FIG. 1, a conventional test jig for printed circuit boards includes a pin board 10, a plurality of probes 12 and middle boards 14. The pin board 10 is formed with pin holes 16 corresponding to the positions of to-be-tested devices 13 of a to-be-tested object 11 (a printed circuit board in this example). Each probe 12 is composed of a probe sleeve 18, a cylinder 20, a spring 22 and a probe body 24. The probe sleeve 18 is inserted into a predetermined pin hole 16 of the pin board 10 and has one end connected to a wire 19 for transmitting signals to a test machine (not shown). The spring 22 is received within the cylinder 20 into which the probe body 24 is inserted. According to the retractable force of the spring 22, the probe body 24 is retractable within the cylinder 20. Then, the cylinder 20 is mounted within the probe sleeve 18. Accordingly, the overall probe 12 is mounted on the pin board 10. The middle board 14 is also formed with middle holes 26 corresponding to the pin holes 16 of the pin board 10, respectively. The probe body 24 passes through a predetermined middle hole 26 of the middle board 14, projects over the middle board 14, and passes through a predetermined through hole 17 formed on a top board 15 located above the middle board 14.

Thereafter, a printed circuit board 11 is placed above the top board 15, and the test machine is used to make the to-be-tested device 13 of the printed circuit board 11 in contact with the probe body 24 of the probe 12. Then, electrical signals are in turn transferred to the spring 22, the probe sleeve 18, and the test machine via the wire 19 connected to the bottom of the probe sleeve 18. Next, the test machine judges whether or not the to-be-tested device can be turned on, and the test process of the printed circuit board 11 is thus completed.

The conventional test jig has the following drawbacks.

1. When the probe 12 contacts the to-be-tested device 13 of the to-be-tested object 11, the probe 12 has to possess retractable restoring force so that the electrical property of the to-be-tested device 13 can be free from being damaged. Therefore, the probe body 24 has to be placed within the cylinder 20 having the spring 22 mounted therein so as to automatically restore to its initial state before being compressed. In such a structure, the overall volume of the probe 12 cannot be easily made small. Thus, the manufacturing cost of the probe 12 is high when it is made very small, thereby increasing the testing cost. Accordingly, the test density cannot be effectively increased.

2. Since the size of the probe sleeve 18 has to mate with that of the probe 12, the size of the probe sleeve 18 is correspondingly limited and the overall test density of the pin holes 16 of the pin board 10 cannot be increased. Therefore, the circuit board 11 having to-be-tested devices 13 with a high density cannot be tested.

3. Since the electrical signals from the to-be-tested device 13 of the printed circuit board 11 are transferred via the contacts between the probe body 24 and the resilient member 22, between the resilient member 22 and the cylinder 20, and between the cylinder 20 and the probe sleeve 18, the phenomenon of poor signal transfer effects may occur after multiple contacts between such members. Thus, the test quality for the printed circuit board may be influenced, and especially poor in testing the to-be-tested devices with a high density.

4. Since the probe 12 is mounted on the pin board 10 and is not detachable, the pin board 10 and the probe 12 may not be used after a batch of printed circuit boards is tested. Therefore, the testing cost is increased and the source is wasted.

5. Since the probe 12 is vertically in contact with the printed circuit board 11, the probe 12 has to be made relatively thin and small when the density of the to-be-tested devices 13 on the printed circuit board 11 is high, thereby increasing the cost of the probe 12.

In view of this, a reusable test jig is provided to overcome the above-mentioned drawbacks.

### SUMMARY OF THE INVENTION

It is therefore an object of the invention to provide a reusable test jig that can be easily manufactured so as to lower the manufacturing cost.

Another object of the invention is to provide a reusable test jig capable of testing the to-be-tested devices with a higher density and decreasing the testing cost.

Still another object of the invention is to provide a reusable test jig capable of improving the testing conductivity so as to obtain better testing effects.

Yet still another object of the invention is to provide a reusable test jig that can be recycled to lower the manufacturing cost.

To achieve the above-mentioned objects, the invention provides a reusable test jig including a pin board unit, a plurality of electroconductive resilient members, a plurality of wires, a holding plate unit and a plurality of probes. The pin board unit is formed with pin holes corresponding to the to-be-tested devices of the to-be-tested object. The electroconductive resilient members are received within the pin holes of the pin board unit and can elastically move back and forth within the pin holes, respectively. Each resilient member includes a first terminal and a second terminal. Each wire includes an upper terminal and a lower terminal. The upper terminals are electrically connected to the first terminals of the corresponding resilient members. The signals are transferred to the test machine via the lower terminals. The holding plate unit is formed with holding holes corresponding to multiple pins of the to-be-tested object. At least one of the holding holes is properly inclined. The probes are inserted into and held by the holding holes of the holding plate unit, respectively. Each probe includes a first terminal and a second terminal. The first terminals electrically contact the second terminals of the resilient members, respectively. The second terminals project over the holding plate unit and contact the to-be-tested devices of the to-be-tested object.

### BRIEF DESCRIPTION OF THE DRAWINGS

FIG. 1 is an exploded view showing a conventional test jig.

FIG. 2 is an exploded view showing a reusable test jig of the invention.

FIG. 3 is another implementation drawing showing the pin board unit of the invention.

FIG. 4 is a cross-sectional view showing the combination of FIG. 2.

FIG. 5 is an implementation drawing of FIG. 4.

FIG. 6 is another schematic illustration of the invention.

FIG. 7 is an implementation drawing of FIG. 6.

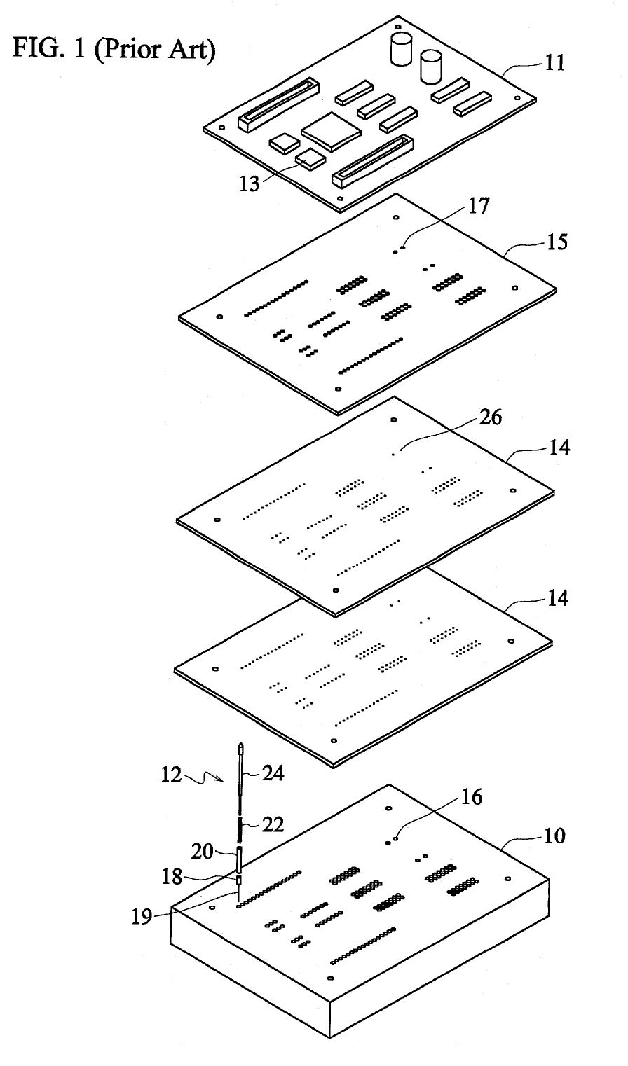

### DETAILED DESCRIPTION OF THE INVENTION

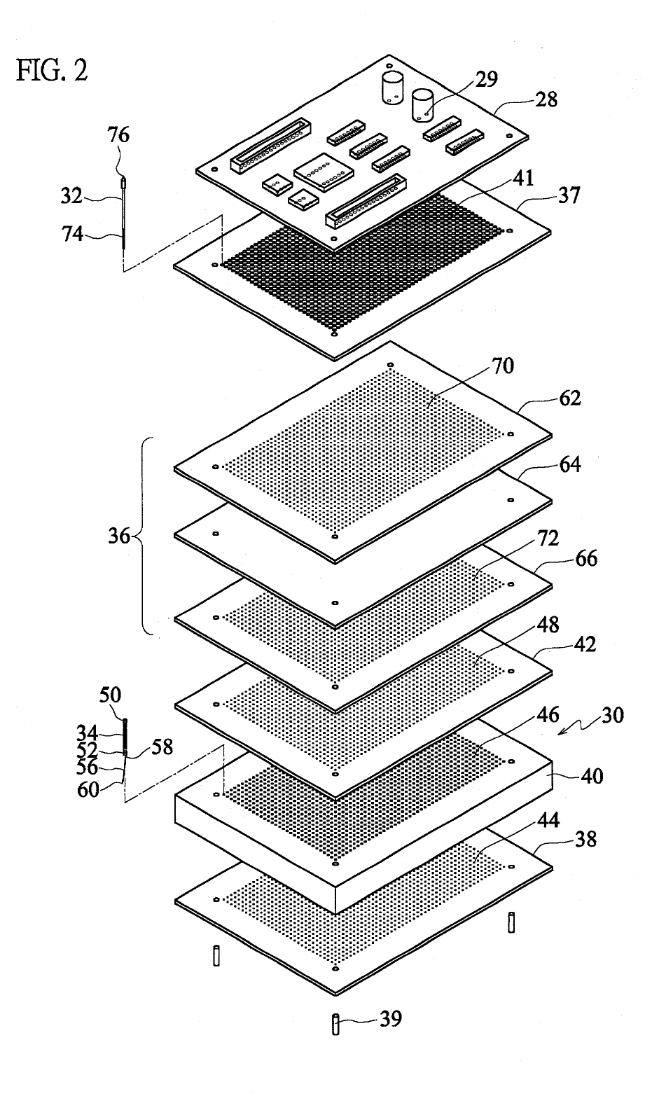

Referring to FIG. 2, the reusable test jig of the invention is used to test a to-be-tested object 28 having a plurality of to-be-tested devices 29. The to-be-tested object 28 may be a printed circuit board, a semiconductor package element or a wafer. The test jig includes a pin board unit 30, a plurality of probes 32 (only one is shown in the drawing), a plurality of electroconductive resilient member 34 (only one is shown in the drawing), a holding plate unit 36 and a plurality of support columns 39.

The pin board unit 30 is composed of a lower pin board 38, a middle pin board 40 and an upper pin board 42. The lower pin board 38 is formed with lower pin holes 44 arranged in a grid-like and crisscross fashion. The distance between two adjacent lower pin holes 44 may equal to or smaller than 1.27 mm so as to be suitable for testing the to-be-tested devices 29 having a higher density. The middle pin board 40 is stacked on the lower pin board 38, and also formed with middle pin hole 46 arranged in a grid-like and crisscross fashion. The diameter of each middle pin hole 46 is greater than that of each lower pin hole 44. The distance between two adjacent middle pin holes 46 may equal to or smaller than 1.27 mm so as to be suitable for testing the to-be-tested devices 29 having a higher density. The upper pin board 42 is stacked on the middle pin board 40, and also formed with upper pin holes 48 arranged in a grid-like and crisscross fashion. The diameter of each upper pin hole 48 is smaller than that of each middle pin hole 46. The distance between two adjacent upper pin holes 46 may equal to or smaller than 1.27 mm so as to be suitable for testing the to-be-tested devices 29 having a higher density.

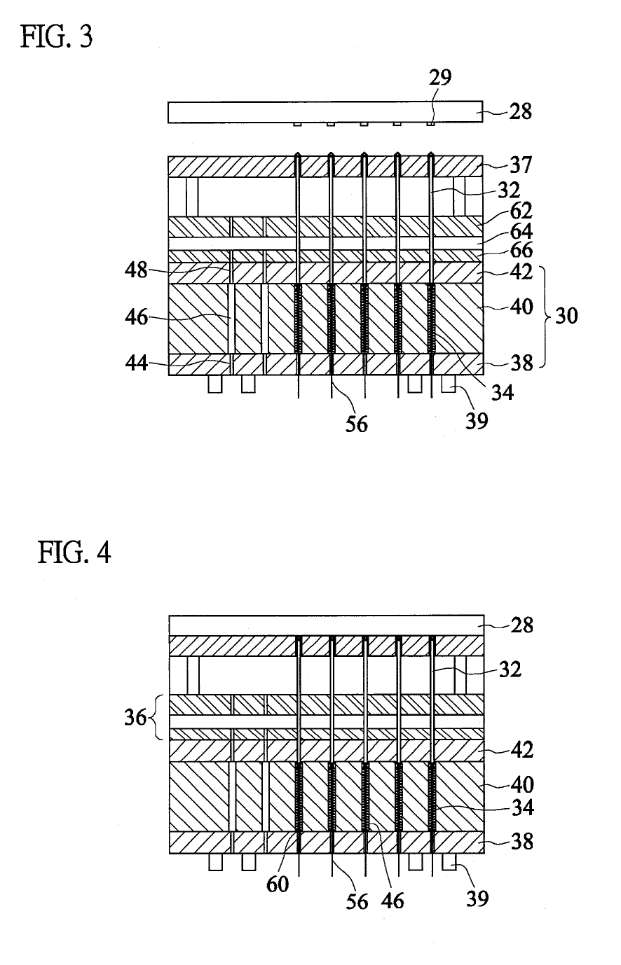

Referring to FIG. 3, the pin board unit 30 includes the lower pin board 38, the middle pin board 40 and an upper pin board 42. The lower pin board 38 is formed with the lower pin holes 44 corresponding to the pins of the to-be-tested devices 29 on the to-be-tested object 28. The middle pin board 40 is formed with the middle pin holes 46 corresponding to the pins of the to-be-tested devices 29 on the to-be-tested object 28. Also, the upper pin board 42 is formed with the upper pin holes 48 corresponding to the pins of the to-be-tested devices 29 on the to-be-tested object 28. The diameter of the middle pin hole 46 is greater than that of either the upper pin hole 48 or the lower pin hole 44.

Referring to FIGS. 2 and 3, the resilient member 34 includes a first terminal 50 and a second terminal 52. The first terminal 50 has a support portion 54 with a decreased diameter while the second terminal 52 is electrically connected to an upper terminal 58 of an electroconductive member 56 (a wire in this embodiment). The electroconductive member 56 connecting to the resilient member 34 is inserted into the middle pin hole 46 and the lower pin hole 44 of the middle pin hole 46 and lower pin hole 44 corresponding to the to-be-tested device 29, respectively. The second terminal 52 of the resilient member 34 is rested on the lower pin hole 44. The resilient member 34 is received within the middle pin hole 46 and is capable of elastically sliding back and forth within the middle pin hole 46. The upper pin board 42 is placed above the middle pin board 40 to restrict the resilient member 34 and prevent the resilient member 34 from escaping out of the middle pin hole 46. The lower terminal 60 of the electroconductive member 56 is used to transfer the electrical signals from the to-be-tested device 29 of the to-be-tested object 28 to the test machine (not shown). In addition, the electroconductive member 56 also may be a conductive column (not shown) inserted into a predefined through hole of a printed circuit board for transferring test signals to the test machine via the printed circuit board.

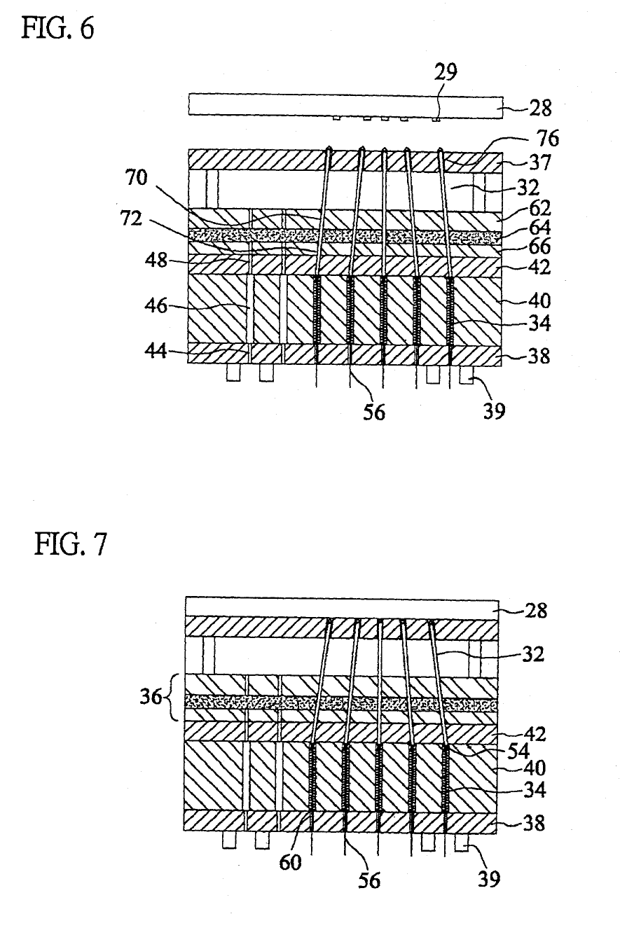

The holding plate unit 36 includes an upper holding plate 62, a lower holding plate 66 and a flexible board 64 interposed therebetween. The upper holding plate 62 and lower holding plate 66 are formed with upper holding holes 70 and lower holding holes 72 corresponding to a plurality of pins of the to-be-tested device 29 on the to-be-tested object 28, respectively. At least one set of the upper holding hole 70 and its corresponding lower holding hole 72 is inclined (as shown in FIG. 6).

Each probe 32 may be made of copper and its surface is coated with nickel to improve its conductivity. Each probe 32 is inserted into the upper holding hole 70 and lower holding hole 72 of the upper holding plate 62 and lower holding plate 66 of the holding plate unit 36, respectively, corresponding to the position of each to-be-tested device 29 of the to-be-tested object 28. Each probe 32 plunges through the flexible board 64 and is held or fixed by the flexible board 64. The probe 32 includes a first terminal 74 and a second terminal 76. The first terminal 74 contacts the support portion 54 of the first terminal 50 of the resilient member 34. On the other hand, the second terminal 76 projects over the upper holding plate 62 of the holding plate unit 36 for electrically contacting the to-be-tested device 29 of the to-be-tested object 28.

A top board 37 is provided at a suitable distance above the holding plate unit 36. The top board 37 is formed with through holes 41 corresponding to the positions of the to-be-tested device 29 of the to-be-tested object 28. Accordingly, the probe 32 passes through the through hole 41 with its second terminal 76 projecting over the top board 37 and contacting the to-be-tested device 29. At least one through hole 41 of the top board 37 is inclined with respect to the upper holding hole 70 and the lower holding hole 72 so that at least one probe 32 is inclined. The inclined probe 32 may contact the to-be-tested device 29 of the to-be-tested object 28 and the testing density is thus increased.

The support column 39 is mounted on the bottom of the lower pin board 38 where no resilient member 34 is inserted, so as to support and enhance the pin board unit 30 and prevent the pin board unit 30 from being damaged under the depression of the to-be-tested object 28.

As shown in FIGS. 2 and 4, the resilient member 34 connecting to the electroconductive member 56 is inserted into the middle pin hole 46 of the middle pin board 40, and is restricted by the upper pin board 42 and the lower pin board 38. In addition, the resilient member 34 is elastically retractable within the middle pin hole 46. The holding plate unit 36 is mounted above the pin board unit 30. Each probe 32 is inserted from the upper holding hole 70 and lower holding hole 72 to the upper pin hole 48 and middle pin hole 46 of the pin board unit 30. Meanwhile, the first terminal 74 of the probe 32 is caused to contact the support portion 54 of the resilient member 34. Thus, the probe 32 is elastically retractable and can be automatically and properly guided.

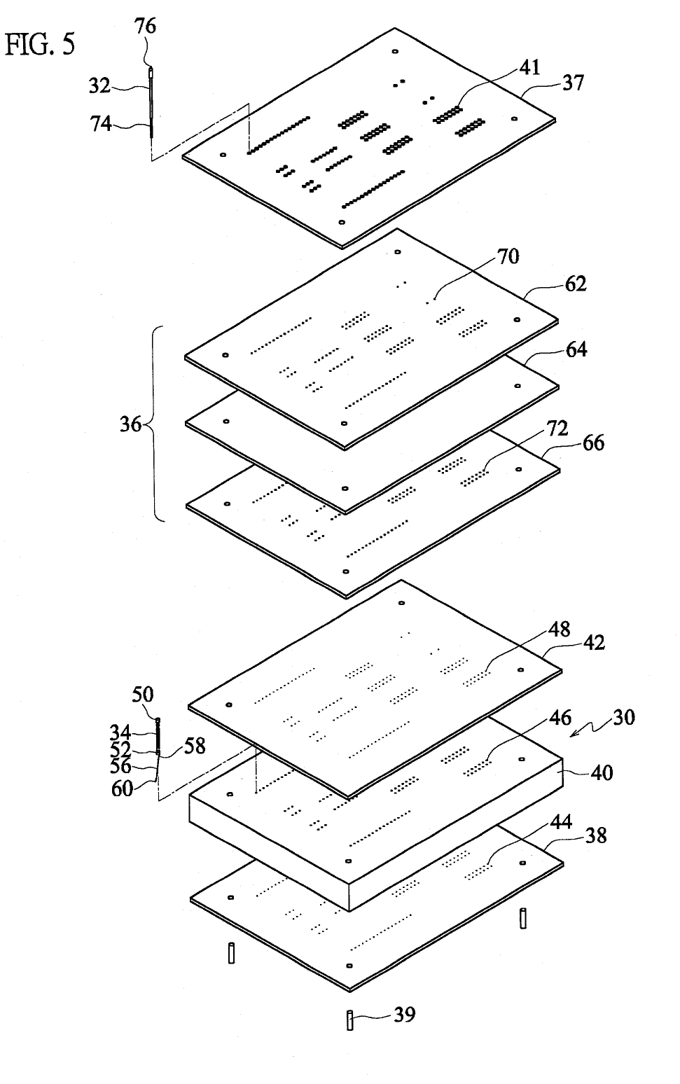

As shown in FIGS. 2 to 5, the to-be-tested object 28 is placed above the holding plate unit 36 with probes 32 inserted therein. The to-be-tested devices 29 on the to-be-tested object 28 are aligned and in contact with the corresponding probes 32 so that signals can be transferred to the resilient member 34. The signals are transferred to the test machine via the electroconductive members (wires in this embodiments) 56 of the lower terminal 60 connecting to the resilient member 34. The test machine judges whether or not the to-be-tested devices are conductive or perfect. In addition, the electroconductive members 56 may be conductive columns ( not shown ) inserted into a printed circuit board for transferring test signals to the test machine via the printed circuit board.

The probes 32 contacts and presses against the support portions 54 of the resilient members 34, and may be automatically and properly guided.

As shown in FIGS. 6 and 7, when the density of the to-be-tested devices 29 of the to-be-tested object 28 is very high, the upper holding holes 70 of the holding plate unit 36 and the corresponding lower holding holes 72 may be inclined. Thus, the probes 32 may be inserted into the upper holding hole 70 and lower holding hole 72 in a slant manner to contact the resilient members 34 within the pin board unit 30. Since the probes 32 are arranged in a slant manner, it is possible to test the to-be-tested devices 29 having a higher density.

The above-mentioned test jig of the invention has the following advantages.

1. Since the resilient members 34 are inserted into the middle pin holes 46 of the pin board unit 30 and then contacts the probes 32 directly, the probes 32 may be made simple, thin, and low-cost. Thus, the testing cost may be lowered.

2. Since the resilient members 34 directly contact the wires 56, the signals from the to-be-tested devices 29 are transferred via only the probes 32 and the resilient members 34. Thus, better signal transmission effects can be obtained and the testing effects can be improved.

3. Since the pin board unit 30 is formed with pin holes arranged in a grid-like and crisscross fashion, the test jig can be combined by placing the resilient members 34 within the corresponding pin holes according to the positions of the to-be-tested devices 29, and placing the probes 32 on the corresponding resilient members 34. Accordingly, the pin board unit 30 can be used repeatedly in conjunction with the to-be-tested objects 28 with different lot numbers so as to reduce the testing cost.

4. Since the probes 32 can be made relatively thin and low cost, the testing density of the to-be-tested device 29 can be increased.

5. Since the resilient members 34 and probes 32 are selectively inserted into the crisscrossed pin holes of the pin board unit 30, the support columns 39 may be inserted into the through holes where no resilient member 34 is inserted. The density of the pin holes can be increased so as to test the to-be-tested devices 29 with a higher density.

6. Since the probes 32 contact the to-be-tested devices 29 of the to-be-tested object 28 in a slant manner, the testing density can be increased.

7. Since the probes 32 and the resilient members 34 are provided separately, the probes 32 may be recycled and reused even when the resilient members 34 are damaged owing to the elastic fatigue.

What is claimed is:

1. A reusable test jig for testing a to-be-tested object having a plurality of to-be-tested devices and pins and for transferring signals to a test machine, the test jig comprising:
a pin board unit formed with predetermined pin holes corresponding to the to-be-tested devices of the to-be-tested object;
a plurality of electroconductive resilient members inserted into the pin holes of the pin board unit and capable of elastically moving back and forth within the pin holes, each of the resilient members including a first terminal and a second terminal;
a plurality of wires each having an upper terminal and a lower terminal, the upper terminals being electrically connected to corresponding first terminals of the resilient members, and the signals being transferred to the test machine via the lower terminals;
a holding plate unit formed with predetermined holding holes corresponding to the pins of the to-be-tested object, the holding holes penetrating through the holding plate unit; and
a plurality of probes inserted into and penetrating through the holding holes of the holding plate unit, each of the probes including a first terminal and a second terminal, wherein the first terminals contact the second terminals of the resilient members, respectively, and the second terminals project over the holding plate unit and contact the to-be-tested devices of the to-be-tested object, respectively.

2. The reusable test jig according to claim 1, wherein the to-be-tested object is selected from a group consisting of a printed circuit board, a semiconductor package element, and a wafer.

3. The reusable test jig according to claim 1, wherein:
the pin board unit is composed of an upper pin board, a middle pin board and a lower pin board;
each of the pin holes is defined by a middle pin hole in the middle pin board, an upper pin hole in the upper pin board, and a lower pin hole in the lower pin board; and
the middle pin holes are larger than the upper and lower pin holes so that the resilient members are received within the middle pin holes and restricted by the upper and lower pin boards.

4. The reusable test jig according to claim 1, wherein the holding plate unit includes a flexible board, and the probes are inserted into the holding holes of the holding plate unit and plunge through the flexible board so as to be effectively fixed by the flexible board.

5. The reusable test jig according to claim 1, wherein the second terminals of the resilient members are formed with support portions with decreased diameters for contacting the probes.

6. A reusable test jig for testing a to-be-tested object having a plurality of to-be-tested devices and pins and for transferring signals to a test machine, the test jig comprising:
a pin board unit formed with pin holes arranged in a grid-like and crisscross fashion;
a plurality of resilient members inserted into the pin holes of the pin board unit corresponding to the to-be-tested devices of the to-be-tested object and is capable of elastically moving back and forth within the pin holes, each of the resilient members including a first terminal an a second terminal;
a plurality of wires each having an upper terminal and a lower terminal, the upper terminals being electrically connected to corresponding first terminals of the resilient members, and the signals being transferred to the test machine via the lower terminals;
a holding plate unit formed with predetermined holding holes corresponding to the pins of the to-be-tested object, the holding holes penetrating through the holding plate unit;
a plurality of probes inserted into the holding holes of the holding plate unit, each of the probes including a first terminal and a second terminal, the first terminals being inserted into the pin holes of the pin board unit where the resilient members are inserted, and electrically contacting the second terminals of the resilient members, respectively, and the second terminals projecting over the holding plate unit and contacting the pins of the to-be-tested object.

7. The reusable test jig according to claim 6, further comprising support columns provided at a bottom of the pin board unit where no resilient member is provided so as to enhance the pin board unit.

8. The reusable test jig according to claim 6, wherein:
the pin board unit is composed of an upper pin board, a middle pin board and a lower pin board;
each of the pin holes is defined by a middle pin hole in the middle pin board, an upper pin hole in the upper pin board, and a lower pin hole in the lower pin board; and
the middle pin holes are larger than the upper and lower pin holes so that the resilient members are received within the middle pin holes and restricted by the upper and lower pin boards.

9. The reusable test jig according to claim 6, wherein the holding plate unit includes a flexible board, and the probes are inserted into the holding holes of the holding plate unit and plunge through the flexible board so as to be effectively fixed by the flexible board.

10. The reusable test jig according to claim 6, wherein the second terminals of the resilient members are formed with support portions with decreased diameters for contacting the probes and automatically guiding slanted probes.

11. A reusable test jig for testing a to-be-tested object having a plurality of to-be-tested devices and transferring signals to a test machine, the test jig comprising:
a pin board unit formed with predetermined pin holes corresponding to the to-be-tested devices of the to-be-tested object;
a plurality of electroconductive resilient members inserted into the pin holes of the pin board unit and capable of elastically moving back and forth within the pin holes, each of the resilient members including a first terminal and a second terminal;
a plurality of wires each having an upper terminal and a lower terminal, the upper terminals being electrically connected to corresponding first terminals of the resilient members, and the signals being transferred to the test machine via the lower terminals;
a holding plate unit arranged above the pin board unit and formed with predetermined holding holes penetrating therethrough and corresponding to the to-be-tested devices of the to-be-tested object, at least one of the holding holes being inclined; and
a plurality of probes inserted into the pin holes of the pin board unit and contacting the resilient members, respectively, the probes being held by the holding holes of the holding plate unit, so that the at least one probe is inclined and projects over the holding plate unit for contacting at least one of the to-be-tested devices of the to-be-tested object.

12. The reusable test jig according to claim 11, wherein:
the pin board unit is composed of an upper pin board, a middle pin board and a lower pin board;
each of the pin holes is defined by a middle pin hole in the middle pin board, an upper pin hole in the upper pin board, and a lower pin hole in the lower pin board; and
the middle pin holes are larger than the upper and lower pin holes so that the resilient members are received within the middle pin holes and restricted by the upper and lower pin boards.

13. The reusable test jig according to claim 11, wherein the holding plate unit includes a flexible board, and the probes are inserted into the holding holes of the holding plate unit and plunge through the flexible board so as to be effectively fixed by the flexible board.

14. The reusable test jig according to claim 11, wherein the second terminals of the resilient members are formed with support portions for contacting the probes and automatically guiding the probes.

15. A reusable test jig for testing a to-be-tested object having a plurality of to-be-tested devices and transferring signals to a test machine, the test jig comprising:
a pin board unit formed with pin holes arranged in a grid-like and crisscross fashion;
a plurality of resilient members inserted into the pin holes of the pin board unit corresponding to the to-be-tested devices of the to-be-tested object and is capable of elastically moving back and forth within the pin holes, each of the resilient members including a first terminal an a second terminal;
a plurality of wires each having an upper terminal and a lower terminal, the upper terminals being electrically connected to corresponding first terminals of the resilient members, and the signals being transferred to the test machine via the lower terminals;
a holding plate unit formed with predetermined holding holes corresponding to the to-be-tested devices of the to-be-tested object, at least one of the holding holes being inclined; and
a plurality of probes inserted into the pin holes of the pin board unit and contacting the resilient members, respectively, the probes being held by the holding holes of the holding plate unit, so that the at least one probe is inclined and projects over the holding plate unit for contacting at least one of the to-be-tested devices of the to-be-tested object.

16. The reusable test jig according to claim 15, wherein the second terminals of the resilient members are formed with support portions contacting the probes, respectively.

17. A reusable test jig for testing a to-be-tested object having a plurality of to-be-tested devices and transferring signals to a test machine, the test jig comprising:
a pin board unit formed with predetermined pin holes corresponding to the to-be-tested devices of the to-be-tested object;
a plurality of electroconductive resilient members inserted into the pin holes of the pin board unit and capable of elastically moving back and forth within the pin holes, each of the resilient members including a first terminal and a second terminal formed with a support portion with a decreased diameter;
a plurality of wires each having an upper terminal and a lower terminal, the upper terminals being electrically connected to corresponding first terminals of the resilient members, and the signals being transferred to the test machine via the lower terminals;
a holding plate unit formed with predetermined holding holes corresponding to the to-be-tested devices of the to-be-tested object, at least one of the holding holes being inclined; and
a plurality of probes inserted into the pin holes of the pin board unit and contacting the support portions of the resilient members, respectively, the probes being held by the holding holes of the holding plate unit, so that the at least one probe is inclined and projects over the holding plate unit for contacting at least one of the to-be-tested devices of the to-be-tested object.

18. The reusable test jig according to claim 17, wherein:
the pin board unit is composed of an upper pin board, a middle pin board and a lower pin board;
each of the pin holes is defined by a middle pin hole in the middle pin board, an upper pin hole in the upper pin board, and a lower pin hole in the lower pin board; and
the middle pin holes are larger than the upper and lower pin holes so that the resilient members are received within the middle pin holes and restricted by the upper and lower pin boards.

19. A reusable test jig for testing a to-be-tested object having a plurality of to-be-tested devices and transferring signals to a test machine, the test jig comprising.
a pin board unit formed with predetermined pin holes corresponding to the to-be-tested devices of the to-be-tested object;
a plurality of electroconductive resilient members inserted into the pin holes of the pin board unit and capable of elastically moving back and forth within the pin holes, each of the resilient members including a first terminal and a second terminal formed with a support portion with a decreased diameter;
a plurality of wires each having an upper terminal and a lower terminal, the upper terminals being electrically connected to corresponding first terminals of the resilient members, and the signals being transferred to the test machine via the lower terminals;
a holding plate unit formed with predetermined holding holes corresponding to the to-be-tested devices of the to-be-tested object, at least one of the holding holes being inclined; and
a plurality of probes inserted into the pin holes of the pin board unit and contacting the support portions of the resilient members, respectively, the probes being held by the holding holes of the holding plate unit, so that the at least one probe is inclined and projects over the holding plate unit for contacting at least one of the to-be-tested devices of the to-be-tested object.

20. The reusable test jig according to claim 19, wherein the holding plate unit includes a flexible board, and the probes plunge through the flexible board when they are inserted into the inclined holding holes of the holding plate unit, so that the probes are effectively fixed by the flexible board.
